(19) United States
(12) Patent Application Publication
(10) Pub. No.: US 2010/0176898 A1
(43) Pub. Date: Jul. 15, 2010

(54) MEMS DEVICE AND METHOD FOR MANUFACTURING THE SAME

(75) Inventor: Ryuji KIHARA, Matsumoto (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/685,720

(22) Filed: Jan. 12, 2010

(30) Foreign Application Priority Data
Jan. 14, 2009 (JP) 2009-005409

(51) Int. Cl. H03H 9/02; H01L 21/3205

(52) U.S. Cl. 333/186; 438/758; 257/E21.294

(57) ABSTRACT

A micro electro mechanical systems (MEMS) device includes a substrate and a MEMS structure formed on the substrate. In the device, the MEMS structure includes an operation structure including a support portion formed on the substrate and a movable portion that is extended from the support portion and movable above the substrate. The movable portion has a section minimum portion whose a sectional area orthogonal to a direction toward the movable portion from the support portion is smaller than a sectional area of the movable portion located on each side of the section minimum portion. The section minimum portion is formed by a boundary pattern provided to a planar pattern of the operation structure.

### BACKGROUND

1. Technical Field

The present invention relates to a MEMS device and a method for manufacturing the same. Particularly, the invention relates to a structure and a manufacturing method that are preferably used for enhancing the frequency accuracy of a MEMS resonator.

2. Related Art

Micro electro mechanical systems (MEMS) are one of techniques for forming microstructures, and include a technique for producing micro electro mechanical systems in a micron-order and products manufactured by the technique. Electronic circuits of a semiconductor chip are formed by stacking thin films of, such as silicon, an oxide film, and metal, on a substrate. Thus, the circuit structure generally has a planer pattern. However, in a case where the MEMS are used as a technique for forming the semiconductor chip, the thin films formed on the substrate is partially separated from the substrate for forming micron-dimensiond plate springs, mirrors, rotation axes, and that like. Accordingly, such a MEMS structure has a stereoscopic structure, and at least a portion thereof has a movable portion.

The MEMS have been drawn attention in the communication technology field for cell phones and the like. In addition to a LSI, the cell phones include many components such as a filter, an antenna switch, a transmit/receive switch, and the like. As the multiband communication, in which Bluetooth and wireless LAN are used, continues to advance, the number of passive components, such as a switch for switching antennas and a switch for switching bands, provided in the cell phone are increased. In order to downdimension the cell phone and reduce its power consumption, reducing the number of components is the effective approach. The number of components is reduced by mounting the above-described components on a single semiconductor chip. In this approach, the wiring lines are shortened and the MEMS component mechanically operates. Accordingly, increasing performance of noise resistance and low loss can be expected. Further, by using a semiconductor, the MEMS component can be joined with conventional existing components by integrating with the LSI, for example. Particularly, in a MEMS resonator, the integration makes it possible to achieve a filter having a loss that is ten or more times smaller than that in a case using the discrete components. Such MEMS resonator is disclosed in JP-T-2007-535275 and JP-T-2007-533186.

The MEMS device, for example may have a structure in which the movable portion of a movable electrode operates by an electrostatic force applied between a fixed electrode and the movable electrode facing each other with a space therebetween. At this time, the performance characteristic of the movable portion of the MEMS device is determined by a mechanical structure of the fixed electrode and the movable electrode as well as an elastic constant of the material of the structure.

However, in the related art MEMS device, the performance characteristic is determined by the structural dimensions as described above. Thus, variations in the structural dimensions at the time of manufacturing cause variations in the performance characteristic. As a result, sufficient device accuracy may not be obtained. For example, in the MEMS resonator, it is considered that the higher the frequency accuracy, the better the characteristic of the resonator. However, limits of accuracy in the structural dimensions generally make it hard to form a MEMS resonator having accuracy corresponding to the frequency accuracy of the related art quartz crystal resonator (about several ppm).

### SUMMARY

An advantage of the invention is to provide a structure and a method for manufacturing the structure that can improve a performance characteristic of a MEMS device.

According to a first aspect of the invention, a micro electro mechanical systems (MEMS) device includes a substrate and a MEMS structure formed on the substrate. In the device, the MEMS structure includes an operation structure including a support portion formed on the substrate and a movable portion that is extended from the support portion and movable above the substrate. The movable portion has a section minimum portion whose a sectional area orthogonal to a direction toward the movable portion from the support portion is smaller than a sectional area of the movable portion. The section minimum portion is formed by a boundary pattern provided to a planar pattern of the operation structure.

According to the aspect, the section minimum portion formed by the boundary pattern provided to the planar pattern of the movable portion is provided to the movable portion of the operation structure. Thus, the rigidity of the section minimum portion becomes lower than its both sides. As a result, the influence of the structure from the section minimum portion to the support portion side on the performance characteristic of the movable portion becomes smaller. Since the rigidity of the section minimum portion is reduced by the boundary pattern, the structural dimensions that largely influence on the performance characteristic are defined by the pattern accuracy on the planer pattern of the boundary pattern of the movable portion of the operation structure. As a result, it is possible to reduce the influence on the performance characteristic due to errors and variations of the structural dimensions except for the pattern accuracy of the movable portion, enabling the performance accuracy of the MEMS device to be enhanced. Such errors and variations include errors and variations of an extension length of the operation structure caused by a pattern shift, for example.

For example, in MEMS resonators, the section minimum portion serves as a vibration node when the movable portion is vibrated. Accordingly, the influence by the planer shape of the movable portion is increased while the influence by the structure from the section minimum portion to the support portion side is decreased. Consequently, it is possible to enhance the frequency accuracy.

In the MEMS device, the boundary pattern may be a notch formed on a side edge of the operation structure. The boundary pattern is formed by the notch provided on the side edge of the operation structure, i.e., on the edge portion of the operation structure extended toward the movable portion from the support portion. As a result, the rigidity of the section minimum portion is easily reduced by changing the shape of the outer edge of the planer pattern.

Preferably, in the device, the notch is formed on each side edge of the operation structure. The notches formed on each side edge of the operation structure allow the rigidity of the section minimum portion to be further reduced.

Preferably, in the device, the movable portion is cantilever-supported by the support portion. Since it is only necessary that the movable portion is movably supported by the support portion, both side of the movable portion may be supported by the support portions. However, the movable portion cantilever-supported by the support portion allows the structure of the operation structure to be simplified. As a result, designing and manufacturing are simplified, reducing the manufacturing costs.

Preferably, in the device, a width of the support portion is larger than a width of the movable portion. By forming the width of the support portion larger than that of the movable portion, the rigidity of the support portion with respect to the movable portion is increased. Consequently, it is possible to further reduce the influence on the performance characteristic of the MEMS device by the structure except for the movable portion. For example, in the MEMS resonator, the vibration node steadily and accurately generate at the movable portion. As a result, the variation of the resonant frequency is reduced.

Further, in the structure above, by forming the width of the support portion larger than that of the movable portion, not only the rigidity is enhanced but also the stability of the operation is enhanced by preventing unwanted twists of the structure, suppressing operations expect for the original operation of the movable portion.

Preferably, in the device, the operation structure further includes a fixed electrode fixed on the substrate and a movable electrode that includes at least the movable portion and faces the fixed electrode with a space therebetween above the fixed electrode. The movable portion operates in a manner increasing and decreasing the space by an electrostatic force between the fixed electrode and the movable electrode. Such structure can be used for electrostatic resonators, electrostatic switches, electrostatic actuators, and the like.

Preferably, in the device, the MEMS structure is a MEMS resonator in which the movable portion vibrates. Accordingly, the vibration node generates at the section minimum portion. As a result, the variation of the frequency characteristic is reduced, enhancing the frequency accuracy.

According to a second aspect of the invention, a method for manufacturing a micro electro mechanical systems (MEMS) device that includes a substrate and a MEMS structure that is formed on the substrate, and includes an operation structure including a support portion formed on the substrate and a movable portion that is extended from the support portion and movable above the substrate, the method sequentially includes forming a sacrifice layer on the substrate, providing the movable portion on the sacrifice layer so as to form the operation structure, and removing the sacrifice layer. In the method, in forming the operation structure, a section minimum portion whose a sectional area orthogonal to a direction toward the movable portion from the support portion is smaller than a sectional area of the movable portion is formed in the movable portion, and the section minimum portion is formed by a boundary pattern provided to a planar pattern of the operation structure.

According to the aspect, the rigidity of the section minimum portion is reduced. Thus, it is possible to reduce the influence on the performance characteristic caused by the accuracy and variation of the structural dimensions except for the pattern accuracy between the movable portion and the boundary pattern. In this way, the performance accuracy of the MEMS device is improved while the rigidity of the section minimum portion is reduced by providing the boundary pattern to the planer pattern that forms the operation structure. The boundary pattern can be manufactured by simply changing the pattern shape. Accordingly, the boundary pattern can be manufactured without adding complexity to the manufacturing process as well as an increase in the manufacturing costs.

Preferably, in the method, a planar shape of the movable portion and the boundary pattern are formed by a same patterning process. In this way, the structural dimensions of the movable portion, which is extended from the section minimum portion, can be formed with high accuracy, so that the performance accuracy can be further improved. In this case, the planar shape of the movable portion, the boundary pattern, and the planar shape of the support portion are preferably formed by the same patterning process. In this way, in addition to the movable portion and the boundary region, the planar shape of the support portion is formed by the same patterning process. Thus, it is possible to further improve the repeatability of the planer shape of the operation structure including the support portion close to the movable portion. As a result, the performance accuracy is advantageously improved.

### BRIEF DESCRIPTION OF THE DRAWINGS

The invention will be described with reference to the accompanying drawings, wherein like numbers reference like elements.

FIG. 1A is a plan view and FIG. 1B is a sectional view schematically showing a MEMS device according to a first embodiment.

FIG. 2A is a plan view and FIG. 2B is a sectional view showing a first modification of the MEMS device.

FIG. 3A is a plan view and FIG. 3B is a sectional view schematically showing a second modification of the MEMS device.

FIG. 4 is a graph showing dependence of resonant frequency on an extension length in first to third examples and a comparative example.

FIG. 5 is a graph showing dependence of resonator frequency on a width of a support portion in the example.

FIG. 6A is a plan view and FIG. 6B is a sectional view schematically showing a structure of the comparative example.

FIGS. 7A to 7C are plan views showing a variation of the extension length by a pattern shift in the comparative example.

FIGS. 8A to 8C are plan views describing a variation of the extension length by a pattern shift in the example.

FIGS. 9A and 9B are sectional views schematically showing a process for manufacturing the MEMS device according to a second embodiment.

FIGS. 10A and 10B are sectional views schematically showing the process for manufacturing the MEMS device according to the second embodiment.

FIGS. 11A and 11B are sectional views schematically showing the process for manufacturing the MEMS device according to the second embodiment.

FIGS. 12A and 12B are sectional views schematically showing the process for manufacturing the MEMS device according to the second embodiment.

FIG. 13 is a plan view schematically showing other examples of boundary patterns.

### DESCRIPTION OF EXEMPLARY EMBODIMENTS

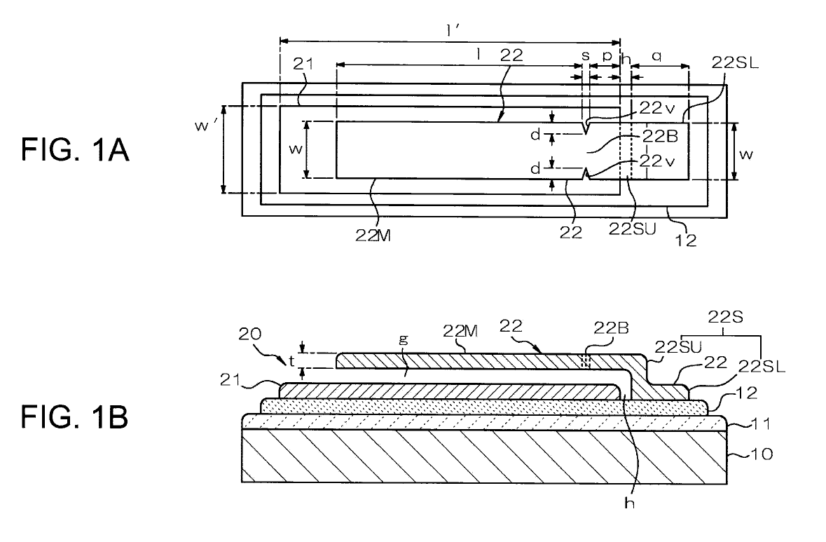

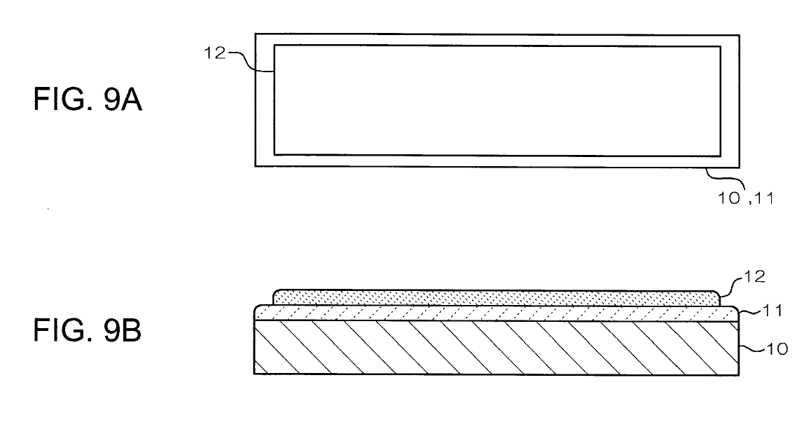

Embodiments of the invention will be described in detail with reference to the accompanying drawings. A micro electro mechanical systems (MEMS) device and a method for manufacturing thereof according to the invention will be described with reference to FIGS. 1A and 1B as well as FIGS. 9A to 12B. FIG. 1A is a plan view and FIG. 1B is a sectional view schematically showing the MEMS device according to a first embodiment. FIGS. 9A, 10A, 11A, and 12A are plan views and FIGS. 9B, 10B, 11B, and 12B are sectional views schematically showing a process for manufacturing the MEMS device according to the first embodiment. Though the MEMS device to be described is a MEMS resonator, the invention is not limited to the MEMS resonator as described below.

### First Embodiment

As shown in FIGS. 1A and 1B, the MEMS device according to the first embodiment includes a MEMS structure 20 formed on a substrate (wafer) 10 serving as a base. The substrate 10 is formed of a semiconductor or the like such as monocrystalline silicon. The substrate 10 is not limited to the semiconductor, and can be formed of various materials such as glass, ceramics, and resin.

### Second Embodiment

As shown in FIGS. 9A and 9B, an insulation film 11 formed of silicon oxide or the like is formed on a surface of the substrate 10 if necessary, so that the insulation with the substrate 10 is ensured. The insulation film 11 is unnecessary in a case where the substrate 10 is formed of a material having a high insulation property such as glass, ceramics, resin, and a low doped semiconductor, or in a case of using a substrate having an insulation film formed on a surface thereof (e.g., an SOI substrate or the like).

Formed on the surface of the substrate 10 is a base layer 12 having resistance to an etching process, such as release etching, described below. The base layer 12 is formed of a silicon nitride film formed by a CVD method or the like if a general silicon-based semiconductor manufacturing technique is employed. The base layer 12 is preferably formed in a limited region required in the etching process.

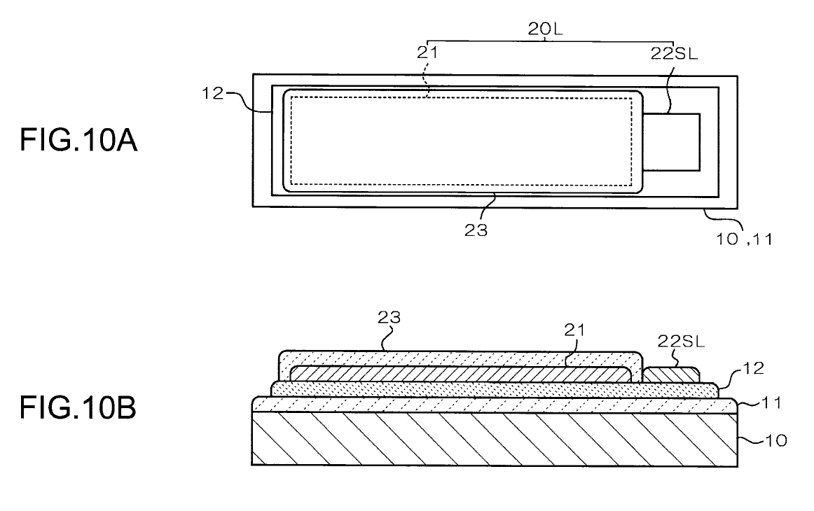

As shown in FIGS. 10A and 10B, formed on the substrate 10 by a predetermined patterning is an underlying pattern 20L formed of a conductive material. The underlying pattern 20L includes a lower structure portion 21 and a lower support portion 22SL. The lower structure portion 21 can serve as a fixed electrode (and its wiring portion if necessary). The lower support portion 22SL is spaced from the lower structure portion 21 so as to be isolated. Formed on the lower structure portion 21 is a sacrifice layer 23 formed of silicon oxide or the like. In the drawing, the sacrifice layer 23 is formed so as to entirely cover the lower structure portion 21. This is a step for forming a sacrifice layer on a substrate. In this case, though the sacrifice layer 23 can be formed by the CVD method or a sputtering method, it may be formed by oxidizing a surface of the lower structure portion 21. For example, in a case where the lower structure portion 21 is formed of a silicon layer, a silicon thermal oxide film formed by a thermal oxidation method can be employed as the sacrifice layer 23.

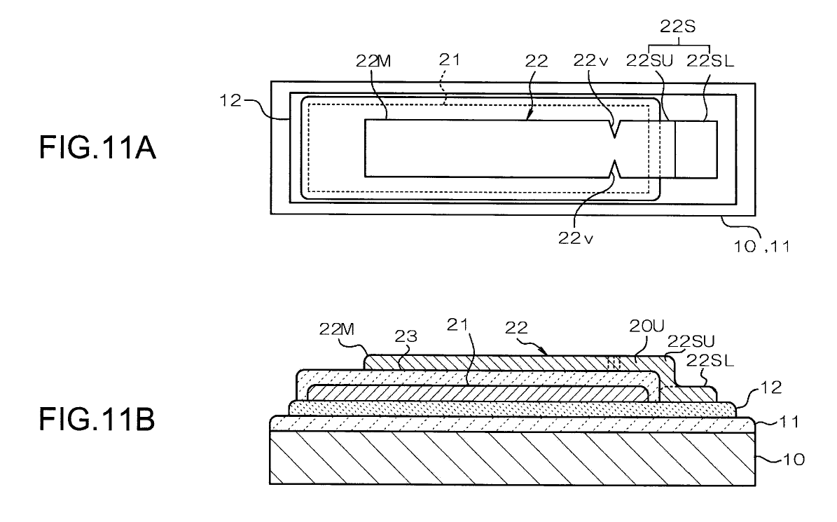

As shown in FIGS. 11A and 11B, formed on the sacrifice layer 23 and the lower support portion 22SL is an overlying pattern 20U formed of a conductive material. The overlying pattern 20U includes a movable portion 22M and an upper support portion 22SU. The movable portion 22M is formed on the sacrifice layer 23. The upper support portion 22SU supports the movable portion 22M. The movable portion 22M includes notches 22v on side edges in a width direction of the overlying pattern 20U. The notches 22v are formed in a projected manner inwardly of the width direction from the side edges of the overlying pattern 20U. In the drawing, the notches 22v are formed so as to face each other on both side edges of the overlying pattern 20U. By forming the overlying pattern 20U on the underlying pattern 20L, an upper structure portion 22 is completed.

The upper structure portion 22 includes the lower support portion 22SL and the overlying pattern 20U. The upper structure portion 22 corresponds to an operation structure that includes the movable portion 22M provided on the sacrifice layer 23 and a support portion 22S having the lower support portion 22SL and the upper support portion 22SU. The notches 22v are simultaneously formed with patterns of the movable portion 22M and the upper support portion 22SU when the overlying pattern 20U is patterned, for example, in a patterning step (patterning etching) of the overlying pattern after a film forming step. In this way, the operation structure is formed by providing the movable portion 22M on the sacrifice layer. In this way, the MEMS structure 20 is completed.

In the MEMS structure 20, as shown in the drawing, the movable portion 22M faces to the lower structure portion 21 with the sacrifice layer 23 interposed therebetween. Though the movable portion 22M is fixed on the substrate 10 in FIGS. 11A and 11B, it eventually becomes movable through the steps described below. In the embodiment, the underlying pattern 20L and the overlying pattern 20U are formed of a conductive material. However, it is only necessary that at least the lower structure portion 21 and the movable portion 22M are formed of a conductive material so as to make the MEMS structure 20 operate.

As such conductive material, it is preferable to use silicon having conductivity. For example, such silicon includes polysilicon to which n-type dopant, such as phosphorus, is doped as an impurity or amorphous silicon. The dopant is not limited to the n-type but also p-type dopant, such as boron, can be used. These materials can be easily formed into a film by the CVD method, the sputtering method, or the like. Any conductive material may be used as long as it has enough conductivity for the operation of the MEMS structure 20. For example, the material may be metal such as aluminum.

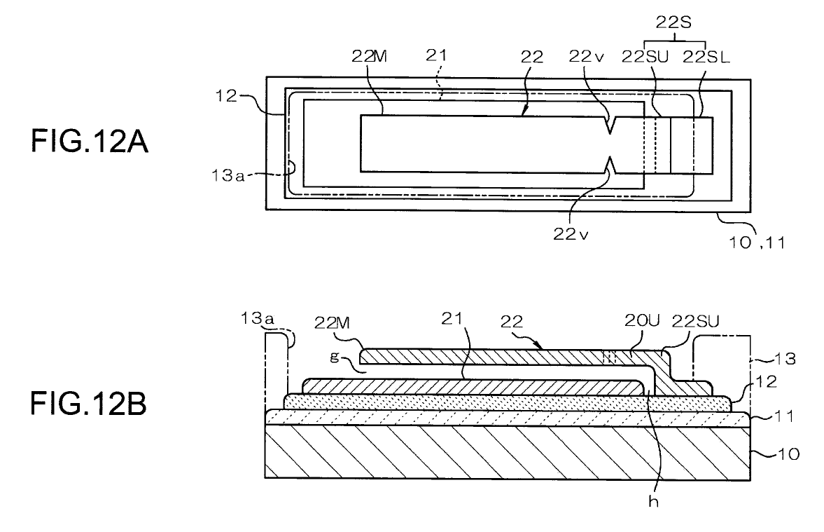

As shown in FIGS. 12A and 12B, a protective layer 13 having an opening 13a is formed on a surface of the structure if necessary. The opening 13a allows at least the sacrifice layer 23 of the MEMS structure 20 to be externally exposed. In the drawings, the opening 13a is formed so as to expose the movable portion 22M and the sacrifice layer 23 in the forming region of the base layer 12. The MEMS structure 20 is entirely covered by the protective film 13 except for the forming region of the base layer 12. The protective film 13 is not particularly limited, but a resist mask can be used that has the opening 13a formed by applying a photosensitive resist, and exposing and developing the photosensitive resist. The protective film 13 protects areas that do not require etching in a release step described below.

The sacrifice layer 23 is removed through the opening 13a with an etchant such as hydrofluoric acid and hydrofluoric acid buffer. This is a step for removing a sacrifice layer (the release step). This step allows the movable portion 22M of the MEMS structure 20 to be released from the sacrifice layer 23. Consequently, the movable portion 22 becomes movable, i.e., vibratable.

The MEMS structure 20 includes the support portion 22S and the movable portion 22M. The support portion 22S is formed on the substrate 10. The movable portion 22M is extended from the support portion 22S and movable (movably supported) on the substrate 10. Here, the movable portion 22M provided to the overlying pattern 20U faces to the lower structure portion 21 provided to the underlying pattern 20L with a space g therebetween. This allows the movable portion 22M to be movable. Thus, if an alternating current signal is applied between the lower structure portion 21 serving as a fixed electrode and the upper structure section 22 serving as a movable electrode, the movable portion 22M vibrates in a vertical direction in the drawing in a manner increasing and decreasing the space g by an electrostatic force.

As shown in FIGS. 1A and 1B, the movable portion 22M is patterned in a belt-like planar shape defined by a length l, a thickness t, and a width w. The movable portion 22M of the overlying pattern 20U and the support portion 22S have the same width w. Further, the lower structure portion 21 is patterned in a belt-like planer shape defined by a length l′ and a width w′.

The lower structure portion 21 is provided so as to entirely overlap the forming region of the movable portion 22M in a plan view. Further, the lower structure portion 21 extends in both sides in the width direction from a position planarly overlapping the side edges of the movable portion 22M. The amount of the extension of the lower structure portion 21 with respect to the upper structure portion 22 (the movable portion 22M) is sufficiently ensured so that the performance characteristic is not adversely affected by a shift pattern in the width direction.

As described above, the space g corresponding to a thickness of the sacrifice layer 23 is provided between the lower structure portion 21 and the movable portion 22M when viewed in the vertical direction. That is, the movable portion 22M faces the lower structure portion 21 with the space g therebetween. The movable portion 22M has a section minimum portion 22B formed by the notches 22v that reduce the width thereof. In the drawing, each of the movable portion 22M, the section minimum portion 22B, and the upper support portion 22SU has the same space g in the vertical direction with respect to the lower structure portion 21. On the other hand, when viewed in a longitudinal direction along the surface of the substrate 10, the lower structure portion 21 extends to a region planarly overlapping the upper support portion 22SU from a region planarly overlapping the movable portion 22M beyond the section minimum portion 22B. A space h in the longitudinal direction exists between the lower structure portion 21 and the lower support portion 22SL.

In the section minimum portion, the notches 22v, having a depth d, are formed inwardly of the width direction from the side edges of the overlying pattern 20U. In the drawing, the notches 22v are formed in a V-shape in a planar view. The notches 22v are provided as a boundary pattern provided to the section minimum portion 22B of the planar pattern of the overlying pattern 20U. By forming these notches 22v, the section minimum portion 22B has the reduced sectional area compared with the movable portion located on each side of the section minimum portion 22B and the support portion 22S. As a result, the rigidity of the section minimum portion 22B is locally reduced.

First Modification

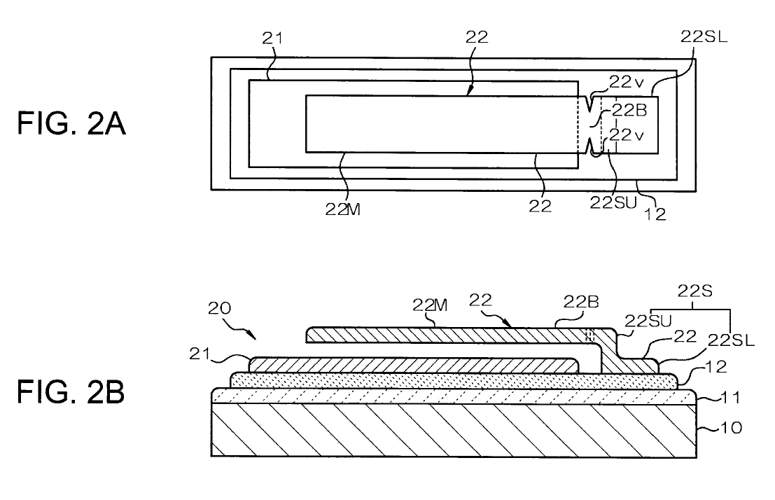

FIG. 2A is a plan view and FIG. 2B is a sectional view schematically showing a first modification of the MEMS device. In the modification, the MEMS device has the same structures as those shown in FIGS. 1A and 1B in respect of the notches 22v are provided to the section minimum portion 22B of the movable portion 22M, for example. However, the MEMS device in the modification differs in that the section minimum portion 22B is provided outside the region planarly overlapping the lower structure portion 21. In other words, the section minimum portion 22B, to which the notches 22v are provided, is provided above the space h between the lower structure portion 21 and the lower support section 22SL. In such structure, by forming the notches 22v, the section minimum portion 22B has the reduced sectional area compared with the movable portion located on each side of the section minimum portion 22B and the support portion 22S. As a result, the rigidity of the section minimum portion 22B is locally reduced.

Second Modification

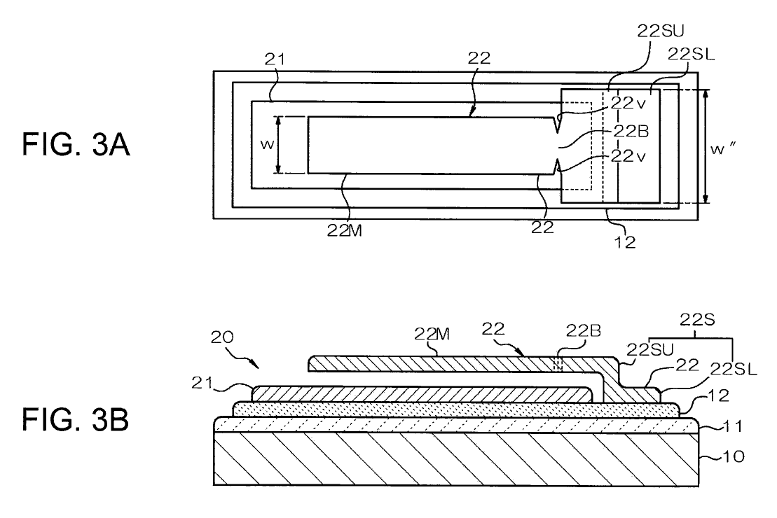

FIG. 3A is a plan view and FIG. 3B is a sectional view schematically showing a second modification of the MEMS device. In the modification, in the operation structure (the upper structure portion 22) that includes the lower support portion 22SL and the overlying pattern 20U, a width w″ of the support portion 22S is formed larger than the width w of the movable portion 22M. In the drawing, the lower support portion 22SL and the upper support portion 22SU are provided so as to correspond in the width direction, having the same width w″. Additionally, in the drawing, the side edges in the width direction of the support portion 22S extends in both sides in the width direction of the movable portion 22M. Thus, the upper structure portion 22 has a T-shape in a planar view. The support portion 22S extends in the same amount in the both side in the width direction from the side edges of the movable portion 22M.

In the MEMS device shown in FIGS. 3A and 3B, the section minimum portion 22B is provided above the lower structure portion 21 in the region planarly overlapping the lower structure portion 21 in the same manner as FIGS. 1A and 1B. However, the section minimum portion 22B may be provided outside the region planarly overlapping the lower structure portion 21 in the same manner as FIGS. 2A and 2B.

### EXAMPLES

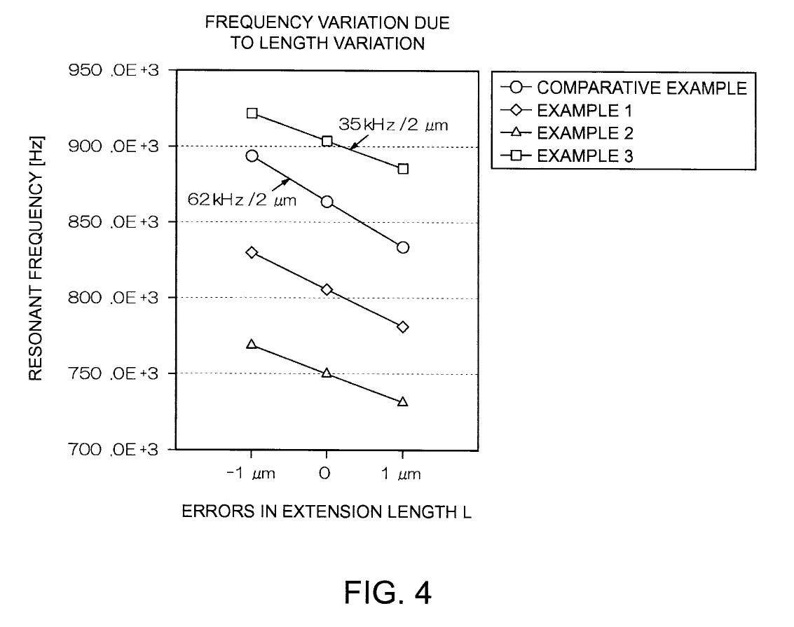

FIG. 4 is a graph showing the dependence of resonant frequency of the MEMS device. In the graph, first, second, and third examples are compared with a comparative example.

In the first example, the l=43 μm, the thickness t=2 μm, the width w=10 μm, the depth d=3 μm, a width s=2 μm, a distance p=5 μm, the space h=2 μm, and a length q=10 μm in the structure shown in FIGS. 1A and 1B where the length l is a length between the end of the movable portion 22M and the boundary position in the end of the notch 22, the depth d is a depth of the notch 22v, the width s is a width of the notch 22v along the side edge, the distance p is a distance between the boundary position in the support 22S side of the notch 22v and the end edge of the lower structure portion 21 in a planar direction, and the length q is a length of the support portion 22S. Here, the length of the movable portion 22M is a length extended from the support portion 22S, i.e., an extension length L=1+s+p+h. The second example has the same structure dimensions as those in the first example except for the depth d=4 μm. The third example has the same structure dimensions as those in the first example except for the width w″ is 20 μm in the structure shown in FIGS. 3A and 3B and the support portion 22S is extended in the same amount in both sides of the width direction of the movable portion 22M.

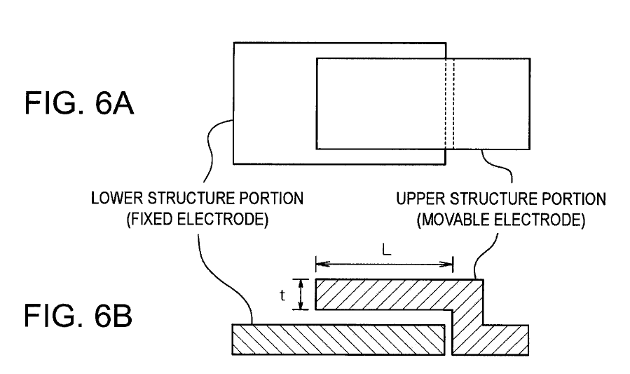

As schematically shown in FIGS. 6A and 6B, the comparative example includes the lower structure portion and the upper structure portion. The lower structure portion includes the overlying pattern and the underlying pattern. The upper structure portion has the movable portion and the support portion provided thereto. The comparative example has the same structure dimensions as those in the first example except for that the notches 22v are not formed. In the comparative example, however, the section minimum portion 22B does not exist since the notches 22v are not provided. Thus, the extension length L of the upper structure portion from the support portion (i.e., the length of the movable portion) corresponds to the total of the length l, the width s, the distance p, and the space h in the first example.

The graph in FIG. 4 shows the result that the variation in the resonant frequency with respect to the variation in the extension length L (=l+s+p+h) (i.e., the length of the movable portion) in the first to third examples and the comparative example are computed by a structural analysis. In any cases, the extension length L (=l+s+p+h) was 52 μm as its baseline value. The structural analyses were respectively performed in a case where the extension length L was increased by 1 μm with respect to the baseline value and in a case where the extension length L was decreased by 1 μm with respect to the baseline value so as to obtain the resonant frequency. In this way, the variation of the resonant frequency due to the variation of the extension length L was derived.

As shown in FIG. 4, the resonant frequency of the comparative example largely varies as the extension length L varies. However, the variation of the resonant frequency of the first to third examples is smaller than that of the comparative example. Specifically, if the variation of the extension length L is 2 μm, the variation of the resonant frequency is 62 kHz in the comparative example while that in the third example is 35 kHz, which is drastically small. As a result, in the second embodiment, the variation of the resonant frequency can be reduced by the notches 22v.

Further, as is apparent from comparing the first and second examples with the comparative example in FIG. 4, the resonator frequency is decreased by the notches 22v. On the other hand, the resonant frequency is increased in the third example. Therefore, the decrease in the resonant frequency due to the notches 22v can be compensated by forming the width w″ of the support portion larger than the width w of the movable portion 22M.

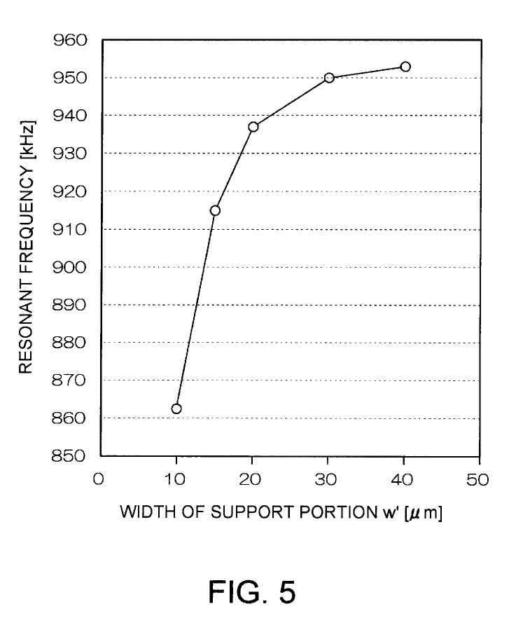

In order to confirm the variation of the resonator frequency, the first example (the one that employs the above-described extension length L as a baseline value) was used as a base, and the resonator frequency was computed by gradually increasing the width w″ in the third example that has the same structural dimensions as those in the first example except for the width w″. The result is shown in FIG. 5. FIG. 5 is a graph showing the dependence of the resonator frequency on the width w″ of the support portion 22S. As is apparent from FIG. 5, the resonant frequency increases as the width w″ becomes larger than the width w. When the width w″ is approximately three times as large as the width w, the resonant frequency is saturated and becomes the substantially constant value.

Thus, as the decrease in the frequency by the notches 22v is compensated by the width w″ of the support portion 22S, the frequency accuracy can be increased without varying the resonant frequency in a case where the notches 22v are not provided. The frequency accuracy can be increased by setting the value of the width w″ to be w<w″. Further, if the width w″ is three or more times larger than the width w, the resonant frequency can be stabilized. As a result, it is possible to further increase the accuracy and the repeatability of the resonant frequency.

The reason why the performance characteristic (the frequency characteristic) shown in the calculated result is obtained can be considered as follows. A resonant frequency Fr of the MEMS structure 20 can be expressed as the following formula 1 when the extension length of the upper structure portion 22 from the support portion is L, the thickness is t, and the influence of the width w is ignored.

$$Fr \sim \frac{1}{2 π} \sqrt{\frac{35 E \cdot {t}^{2}}{33 ρ \cdot {L}^{4}}} \qquad Formula 1$$

In the formula 1, E represents a Young's modulus of the movable portion 22M and ρ represents a density thereof.

From the formula 1, it is obvious that if the extension length L varies, the resonant frequency Fr varies several orders of magnitude compared with a case where the thickness t varies. Further, it is understood that the width w has less influence on the resonant frequency Fr than the thickness t. Therefore, among the structure dimensions of the MEMS structure 20, the extension length L has extremely large influence on the resonant frequency and other frequency characteristics of the MEMS device. As a result, the frequency accuracy of the MEMS device is effectively improved by reducing the influence of the extension length L,

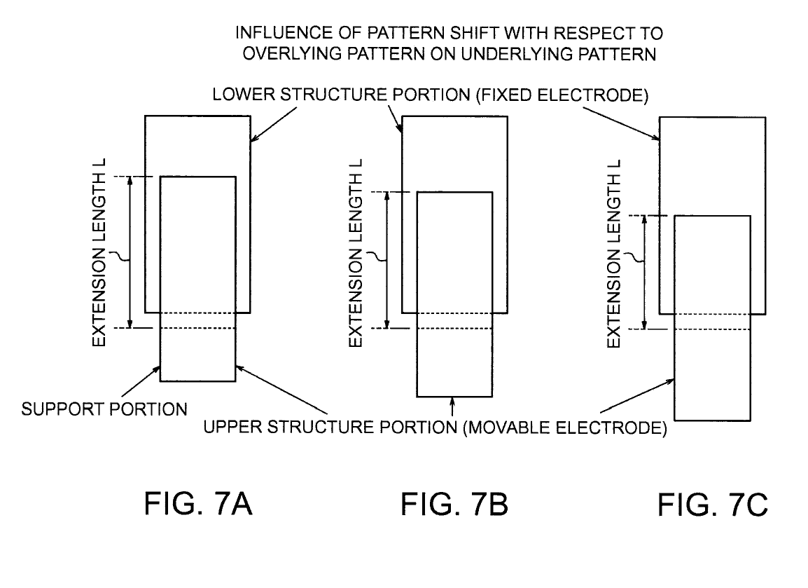

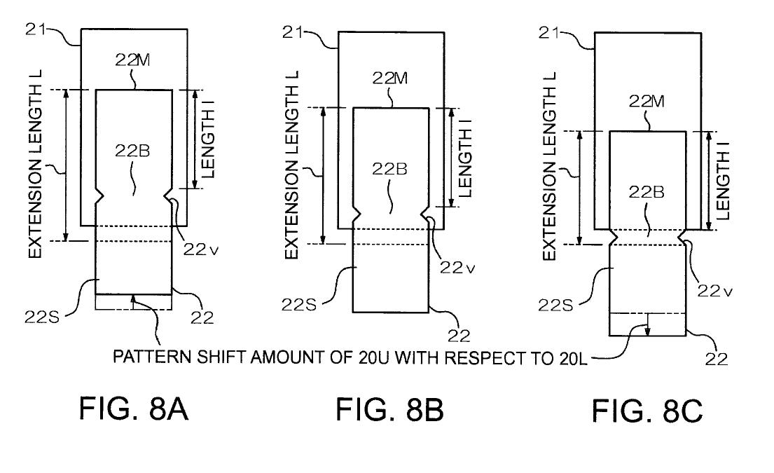

The extension length L varies by a pattern shift in the longitudinal direction of the overlying pattern 20U with respect to the underlying pattern 20L. The pattern shift is, for example, mainly caused by a shift of an exposure pattern (a shift of an exposure mask) in an exposure step when each pattern is formed by a photolithography technique. FIGS. 7A to 7C are plan views for describing the influence of the pattern shift on the comparative example. FIGS. 8A to 8C are plan views for describing the influence of the pattern shift on the examples.

As shown in FIGS. 7A to 7C, in the comparative example, if the overlying pattern 20U is shifted in the longitudinal direction with respect to the underlying pattern 20L, the extension length L of the upper structure portion varies in the same amount as the shift in the longitudinal direction. Accordingly, in a case where the notches 22v do not exist, as the formula 1 shows, the resonant frequency Fr varies in a manner inversely proportional to about the square of the pattern shift.

On the other hand, in the second embodiment, as shown in FIGS. 8A to 8C, if the overlying pattern 20U includes the notches 22v, there is no influence of the pattern shift on the length l though the extension length L varies in the same manner as the comparative example. In this case, the notches 22v allow the rigidity of the section minimum portion to be reduced, generating a vibration node at the section minimum portion 22B. Therefore, the resonant frequency is hardly influenced by the extension length L and is mainly determined by the length l. The pattern accuracy in the overlying pattern 20U is generally far smaller than the pattern shift. Thus, it is considered that the variation of the resonant frequency in the examples is smaller than that in the comparative example.

The frequency characteristic of the MEMS device also is influenced by a variation of the region of the upper structure portion (the movable electrode) 22 overlapping the lower structure portion (the fixed electrode) 21. In other wards, even in a case shown in FIGS. 8A to 8C, strictly speaking, the region of the upper structure portion 22 overlapping the lower structure 22 (a length), for example, a length (=L−h) that the space h is subtracted from the extension length L varies. Accordingly, an electrostatic force that the upper structure portion 22 receives also varies. However, the resonant frequency is simply determined by the length l, other structural dimensions, and an elastic constant of the material, so that the frequency accuracy is improved without any problem. This means that there is no essential difference in the improvement effects of the performance accuracy (the frequency accuracy) between the structures shown in FIGS. 1A, 1B, 3A, and 3B and the structure shown in FIGS. 2A and 2B.

In the manufacturing process, in addition to the pattern shift in the longitudinal direction, a pattern shift in the width direction may occur. However, as described in the second embodiment, the pattern shift in the width direction does not significantly influence on the frequency characteristic of the MEMS device if the lower structure portion (the fixed electrode) 21 is formed so as to be sufficiently extended with respect to the upper structure portion (the movable electrode) 22.

As described above, in the second embodiment, the notches 22v are provided to the movable portion 22M of the upper structure portion 22 (the operation structure) so as to form the section minimum portion 22B. In this way, the rigidity of the section minimum portion 22B is reduced, and the vibration node generates at the section minimum portion 22B. As a result, it is possible to suppress the frequency characteristic from being influenced by the pattern shift of the overlying pattern 20U with respect to the underlying pattern 20L.

The notches 22v are regarded as a portion of the overlying pattern 20U and are simultaneously formed in a step for forming the overlying pattern 20U (a patterning step), so that the length l is determined by the pattern accuracy of the overlying pattern 20U. Thus, the frequency accuracy depending on the length l can be increased to an extent corresponding to the pattern accuracy of the overlying pattern 20U.

Additionally, in the second embodiment, the notches 22v can be manufactured by only changing the pattern of the overlying pattern 20U. Accordingly, the notches 22v can be manufactured without adding complexity to the manufacturing process as well as an increase in the manufacturing costs.

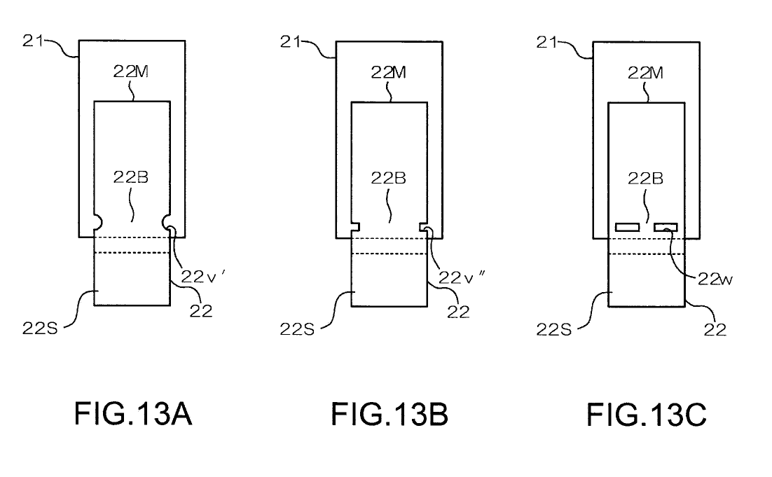

FIGS. 13A to 13C are schematic plan views showing other boundary patterns provided to the section minimum portion 22B. These boundary patterns exemplify a pattern of the section minimum portion 22B except for the notches 22v described above. For example, as shown in FIG. 13A, instead of the notches 22v having a V-shape in a planer view, notches 22v′ having a semicircular shape or a U-shape in a planer view are provided to the section minimum portion 22B. In FIG. 13B, notches 22v″ are formed that have a rectangular shape or a polygonal shape in a planer view. In this way, the planar shape is arbitrarily determined as long as the pattern eventually contributes to a reduction in the rigidity of the section minimum portion 22B.

In FIG. 13C, the notches are not provided to the side edges of the upper structure portion 22 (the overlying pattern 20U). Instead, an opening 22w is provided to the section minimum portion 22B. In the drawing, the section minimum portion 22B has the opening 22w formed in plural numbers along the width direction thereof. In this way, the openings 22w also can contribute to a reduction in the rigidity of the section minimum portion 22B. In other words, the pattern is not particularly limited as long as the section minimum portion 22B is provided by the boundary pattern.

In the second modification, since the width w″ is formed larger than the width w, the rigidity of the support portion 22S is increased. Accordingly, the difference of the rigidity between the support portion 22S and the section minimum portion 22B is increased, steadily and accurately generating the vibration node of the movable portion at the section minimum portion 22B. Consequently, the variation in the resonant frequency can be reduced. For example, as described above, it is possible to compensate the variation in the resonant frequency caused by providing the boundary pattern. In addition, by the rigidity improvement of the support portion 22S, the stability of vibration of the movable portion 22M is improved. As a result, it is possible to suppress an occurrence of other vibration modes except for the original vibration mode.

The method for manufacturing a MEMS device according to the invention is not restricted to those described with reference to the drawings shown above. It should be obvious that various modifications and alterations may be made without departing the scope of the invention. For example, the above-described embodiments exemplify the MEMS device having a cantilever operation structure. However, the MEMS device may have a both-end-supported operation structure in which the support portions are respectively coupled to the both sides of the movable portion. Further, the MEMS device may have an operation structure that includes three or more support portions respectively coupled to the periphery of the movable portion. In those cases, the section minimum portion formed by the boundary pattern is provided to the movable portion.

In the embodiment above, the MEMS resonator is exemplified and described. However, the invention is widely applicable to various MEMS devices such as MEMS actuators, MEMS switches, MEMS sensors (acceleration sensors and pressure sensors), and the like as long as the MEMS device has the movable portion movably supported by the support portion. In the various MEMS devices, the section minimum portion provided to the movable portion allows the performance characteristic of the movable portion to be less influenced by factors except for the structural dimensions of the movable portion. Thus, the influence of the pattern shift can be reduced. Accordingly, it is possible to reduce the variation in the performance characteristic of the movable portion, such as acceleration, moving direction, and movement resistance of the movable portion. As a result, the performance accuracy of the MEMS device can be enhanced.

The entire disclosure of Japanese Patent Application No. 2009-005409, filed Jan. 14, 2009 is expressly incorporated by reference herein.

What is claimed is:

1. A micro electro mechanical systems (MEMS) device, comprising:
a substrate; and
a MEMS structure formed on the substrate, the MEMS structure including:
an operation structure, the operation structure including:
a support portion formed on the substrate; and
a movable portion that is extended from the support portion and movable above the substrate,
wherein the movable portion has a section minimum portion whose a sectional area orthogonal to a direction toward the movable portion from the support portion is smaller than a sectional area of the of the movable portion located on each side of the section minimum portion, and the section minimum portion is formed by a boundary pattern provided to a planar pattern of the operation structure.

2. The MEMS device according to claim 1, wherein the boundary pattern is a notch formed on a side edge of the operation structure.

3. The MEMS device according to claim 2, wherein the notch is formed on each side edge of the operation structure.

4. The MEMS device according to claim 1, wherein the movable portion is cantilever-supported by the support portion.

5. The MEMS device according to claim 1, wherein a width of the support portion is larger than a width of the movable portion.

6. The MEMS device according to claim 1, wherein the operation structure further includes a fixed electrode fixed on the substrate and a movable electrode that includes at least the movable portion and faces the fixed electrode with a space therebetween above the fixed electrode, wherein the movable portion operates in a manner increasing and decreasing the space by an electrostatic force between the fixed electrode and the movable electrode.

7. The MEMS device according to claim 1, wherein the MEMS structure is a MEMS resonator in which the movable portion vibrates.

8. A method for manufacturing a micro electro mechanical systems (MEMS) device that includes a substrate and a MEMS structure that is formed on the substrate and includes an operation structure including a support portion formed on the substrate and a movable portion that is extended from the support portion and is movable above the substrate, the method sequentially comprising:
forming a sacrifice layer on the substrate;
providing the movable portion on the sacrifice layer so as to form the operation structure; and
removing the sacrifice layer,
wherein in forming the operation structure, a section minimum portion whose a sectional area orthogonal to a direction toward the movable portion from the support portion is smaller than a sectional area of the movable portion located on each side of the section minimum portion is formed in the movable portion, and the section minimum portion is formed by a boundary pattern provided to a planar pattern of the operation structure.

9. The method for manufacturing the MEMS device according to claim 8, wherein a planar shape of the movable portion and the boundary pattern are formed by a same patterning process.
